(19) United States
(12) Patent Application Publication
(10) Pub. No.: US 2008/0185655 A1
(43) Pub. Date: Aug. 7, 2008

(54) SMICONDUCTOR DEVICE, METHOD FOR FABRICATING THEREOF AND METHOD FOR INCREASING FILM STRESS

(75) Inventors: Shao-Ta Hsu, Tainan City (TW); Teng-Chun Tsai, Hsinchu (TW); Neng-Kuo Chen, Hsinchu City (TW); Hsiu-Lien Liao, Taichung City (TW); Cheng-Han Wu, Taichung City (TW); Wen-Han Hung, Kaohsiung City (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/670,584

(22) Filed: Feb. 2, 2007

(51) Int. Cl. H01L 21/469; H01L 27/092

(52) U.S. Cl. 257/369; 438/758; 257/E27.062; 257/E21.489

(57) ABSTRACT

A method for forming a semiconductor device is provided. The method comprises steps of providing a substrate having a first-conductive-type transistor and a second-conductive-type transistor formed thereon and then forming a stress layer over the substrate to conformally cover the first-conductive-type transistor and the second-conductive-type transistor. A cap layer is formed on the stress layer over the first-conductive-type transistor. A modification process is performed. The cap layer is removed.

### BACKGROUND OF THE INVENTION

1. Field of Invention

The present invention relates to a semiconductor device and a method for fabricating thereof. More particularly, the present invention relates to a semiconductor device having a high film stress and a method for fabricating thereof.

2. Description of Related Art

As the technology of the semiconductor manufacturing process enters the sub-micron era, the way to improve the device driving current of the N-type metal-oxide semiconductor (NMOS) transistor and P-type MOS transistor attracts a lot of attention. As for the manufacturing process below 65 nanometer (nm), if the driving currents of the NMOS transistor and PMOS transistor can be effectively increased, the time delay of the device can be greatly improved and the operating speed of the device can be increased.

Currently, the industry provides various methods to increase the driving current of the device by using internal stress. The research objects include the shallow trench isolation oxide (STI oxide), the poly-cap silicon nitride (poly-cap SiN) and the contact silicon nitride stop layer film stress. The research reveals that the driving current of the NMOS transistor is increased by applying a tensile stress thereon and the stronger the tensile stress is the more the increment of the driving current is.

However, the increasing of the tensile stress leads to the degradation of the driving current of the PMOS transistor. In order to increase the driving current of the PMOS transistor, it is necessary to apply a compressive stress on the PMOS transistor. Similarly, the compressive stress will lead to the degradation of the driving current of the NMOS transistor. On the other words, the increasing of the tensile stress or the compressive stress of the stress film can increase the driving currents of the NMOS transistor and the PMOS transistor at the same time.

Moreover, as for the current optimal As-deposite technology, the silicon nitride layer with the high tensile stress formed by using the plasma enhanced chemical vapor deposition (PECVD) only can provide the stress of about 1.2 GPa (Giga-Pascal). Comparing to the stress of about 1.6 GPa for the manufacturing process below 65 nm, the silicon nitride layer with the tensile stress of about 1.2 GPa.

Therefore, how to form a stress film with a relatively high tensile stress for increasing the driving current of the NMOS transistor without degrading the performance of the PMOS transistor becomes the most important research task.

### SUMMARY OF THE INVENTION

The present invention is to provide a semiconductor device having a stress layer with a continuous interface and a regional high stress distribution.

The present invention is to provide a method for fabricating a semiconductor device capable of forming a stress layer having a continuous interface and regionally increasing the stress of the stress layer.

The present invention is to provide a method for increasing a stress of a stress layer capable of regionally increasing the stress of the stress layer.

The present invention provides a semiconductor device. The semiconductor device comprises a substrate, a first-conductive-type transistor, a second-conductive-type transistor and a stress layer. The first-conductive-type transistor and the second-conductive-type transistor are disposed on the substrate. The stress layer is disposed over the substrate to cover the first-conductive-type transistor and the second-conductive-type transistor, wherein the thickness of the stress layer over the first-conductive-type transistor is larger than that over the second-conductive-type transistor and the stress layer has a continuous interface.

According to one embodiment of the present invention, the stress layer over the first-conductive-type transistor has a first thickness and the stress layer over the second-conductive-type transistor has a second thickness and the second thickness is 70%˜90% of the first thickness.

According to one embodiment of the present invention, the first-conductive-type transistor is a P-type transistor and the second-conductive-type transistor is an N-type transistor.

According to one embodiment of the present invention, a tensile stress of the stress layer over the N-type transistor is larger than that of the stress layer over the P-type transistor.

According to one embodiment of the present invention, the tensile stress of the stress layer over the N-type transistor is 0.5 GPa˜3.0 GPa larger than that of the stress layer over the P-type transistor.

According to one embodiment of the present invention, a tensile stress of the stress layer over the first-conductive-type transistor is about 0.5 GPa˜1.5 GPa.

According to one embodiment of the present invention, the material of the stress layer is selected from a group consisting of silicon nitride, polysilicon and silicon oxynitride.

According to one embodiment of the present invention, the stress layer is served as an etching stop layer or a conductive cap layer.

The present invention also provides a method for forming a semiconductor device. The method comprises steps of providing a substrate having a first-conductive-type transistor and a second-conductive-type transistor formed thereon and then forming a stress layer over the substrate to conformally cover the first-conductive-type transistor and the second-conductive-type transistor. A cap layer is formed on the stress layer over the first-conductive-type transistor. A modification process is performed. The cap layer is removed.

According to one embodiment of the present invention, the modification process includes a thermal treatment, an ion implantation, a plasma treatment and an oxidation treatment.

According to one embodiment of the present invention, the thermal treatment comprises a UV curing, a spike annealing, an E-beam annealing, a laser annealing and a UV rapid thermal process.

According to one embodiment of the present invention, the first-conductive-type transistor is a P-type transistor and the second-conductive-type transistor is an N-type transistor.

According to one embodiment of the present invention, after the modification process, the stress layer over the N-type transistor is 5%˜30% decreased in thickness.

According to one embodiment of the present invention, after the UV curing, an increment of a tensile stress of the stress layer over the N-type transistor is about 0.5 GPa˜3.0 GPa.

According to one embodiment of the present invention, a tensile stress of the stress layer is about 0.5 GPa˜1.5 GPa.

According to one embodiment of the present invention, the first-conductive-type transistor is an N-type transistor and the second-conductive-type transistor is a P-type transistor.

According to one embodiment of the present invention, after the modification process, a compressive stress of the stress layer over the P-type transistor is increased.

According to one embodiment of the present invention, the material of the stress layer is selected from a group consisting of silicon nitride, polysilicon and silicon oxynitride.

According to one embodiment of the present invention, the stress layer can be served as an etching strop layer or a conductive cap layer.

According to one embodiment of the present invention, the cap layer includes a photoresist layer.

The present invention further provides a method for increasing a stress of a layer suitable for a stress layer disposing over a substrate, wherein the stress layer conformally covers a P-type transistor and an N-type transistor on the substrate and the stress layer has a continuous interface. The method comprises steps of forming a cap layer on the stress layer over the P-type transistor and then performing a modification process to increase a tensile stress of the stress layer over the N-type transistor. The cap layer is removed.

According to one embodiment of the present invention, the modification process includes a thermal treatment, an ion implantation, a plasma treatment and an oxidation treatment.

According to one embodiment of the present invention, the thermal treatment includes a UV curing, a spike annealing, an E-beam annealing, a laser annealing and a UV rapid thermal process.

According to one embodiment of the present invention, after the UV curing, the stress layer is 5%˜30% decreased in thickness.

According to one embodiment of the present invention, after the UV curing, an increment of a tensile stress of the stress layer over the N-type transistor is about 0.5 GPa˜3.0 GPa.

According to one embodiment of the present invention, a wavelength of a UV light used in the UV curing is about 100 nm˜400 nm.

According to one embodiment of the present invention, the UV curing is performed at a pressure of about 3 mTorr˜500 mTorr.

According to one embodiment of the present invention, the cap layer includes a photoresist layer.

In order to make the aforementioned and other objects, features and advantages of the present invention comprehensible, a preferred embodiment accompanied with figures is described in detail below.

### BRIEF DESCRIPTION OF THE DRAWINGS

FIG. 1 is a cross-sectional view showing a semiconductor device according to one embodiment of the present invention.

FIG. 2 is a flow chart illustrating a method for fabricating a semiconductor device according to one embodiment of the present invention.

FIGS. 3A through 3C are cross-sectional views showing a method for fabricating a semiconductor device according to one embodiment of the present invention.

### DESCRIPTION OF EMBODIMENTS

### First Embodiment

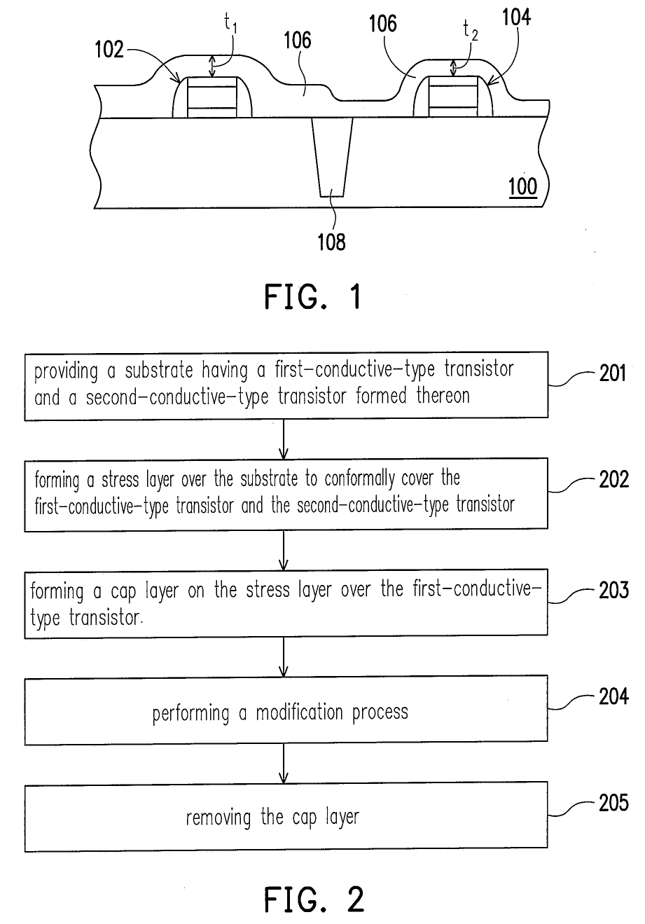

FIG. 1 is a cross-sectional view showing a semiconductor device according to one embodiment of the present invention. As shown in FIG. 1, the semiconductor of the present embodiment comprises a substrate 100, a first-conductive-type transistor 102, a second-conductive-type transistor 104, a stress layer 106 and an isolation structure 108. The substrate 100 can be, for example, a bulk silicon substrate or a silicon-on-insulator substrate. The first-conductive-type transistor 102 and the second-conductive-type transistor 104 are disposed on the substrate 100. In this embodiment, the first-conductive-type transistor 102 can be, for example, a P-type transistor and the second-conductive-type transistor 104 can be, for example, an N-type transistor. Furthermore, the isolation structure 108 can be, for example, a shallow trench isolation structure or a field oxide layer.

The stress layer 106 is disposed over the substrate 100 to cover the first-conductive-type transistor 102 and the second-conductive-type transistor 104. The stress layer 106 has a continuous interface. That is, the interface between the stress layer 106 and the first-conductive-type transistor 102 and the second-conductive-type transistor 104 is a continuous interface. In addition, the surface of the stress layer 106 is a continuous surface. The material of the stress layer 106 can be, for example, selected from a group consisting of silicon nitride, polysilicon and silicon oxynitride.

As shown in FIG. 1, the thickness of the stress layer 106 over the first-conductive-type transistor 102 is denoted as t1 and the thickness of the stress layer 106 over the second-conductive-type transistor 104 is denoted as t2. In this embodiment, t1 is larger than t2 and t2 can be, for example, 70%˜95% of t1.

In one embodiment, the tensile stress of the stress layer 106 over the second-conductive-type transistor 104 is larger than that over the first-conductive-type transistor 102. The tensile stress of the stress layer 106 over the second-conductive-type transistor 104 is about 0.5 GPa˜3.0 GPa larger than that over the first-conductive-type transistor 102. The tensile stress of the stress layer 106 over the first-conductive-type transistor 102 is about 0.5 GPa˜1.5 GPa.

Moreover, the stress layer 106 of the present embodiment can be served as a contact etching stop layer (CESL), a dual CESL or a poly-cap layer in the semiconductor device according to the design demand of the semiconductor device.

The semiconductor device of this embodiment has a stress layer with a continuous interface but with a different thickness. Therefore, the stress of the stress layer can be regional increased. On the other words, the semiconductor device of the present embodiment can have a relatively high driving current for the NMOS transistor without affecting the driving current of the PMOS transistor.

### Second Embodiment

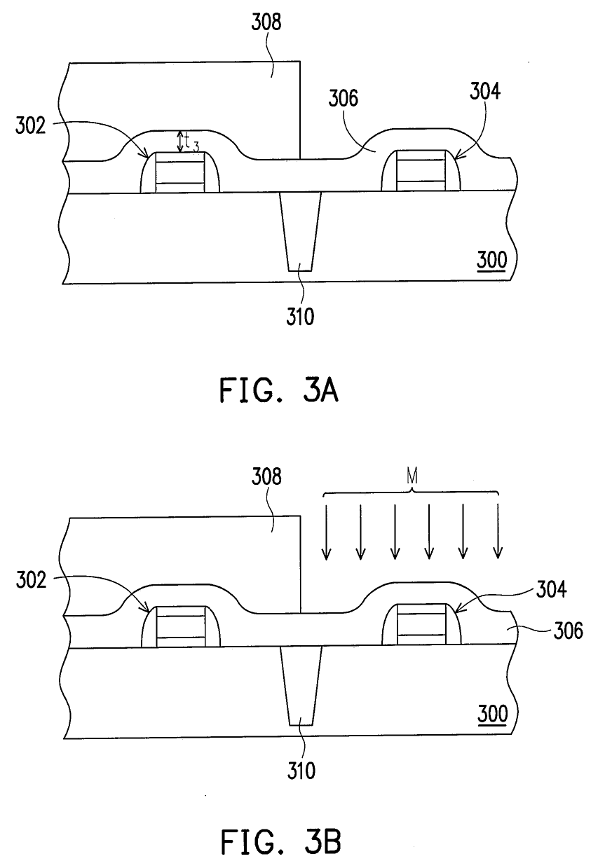

FIG. 2 is a flow chart illustrating a method for fabricating a semiconductor device according to one embodiment of the present invention.

In the step 201, a substrate is provided. The substrate can be, for example, a bulk silicon substrate or a SOI substrate. The substrate has a first-conductive-type transistor and a second-conductive-type transistor formed thereon. Moreover, the substrate comprises an isolation structure such as a STI structure or a field oxide layer formed by LOCOS. In one embodiment, the first-conductive-type transistor can be, for example, an N-type transistor and the second-conductive-type transistor can be, for example, a P-type transistor. Of course, the first-conductive-type transistor can be a P-type transistor and the second-conductive-type transistor can be an N-type transistor.

In the step 202, a stress layer is formed over the substrate to conformally cover the first-conductive-type transistor and the second-conductive-type transistor. In one embodiment, the tensile stress of this stress layer is about 0.5 GPa˜1.5 GPa. Preferably, the tensile stress of the stress layer is about 1.0 GPa˜1.5 GPa. The material of the stress layer can be, for example, selected from a group consisting of silicon nitride, polysilicon and silicon oxynitride. The method for forming the stress layer can be, for example, a chemical vapor deposition (CVD).

Then, in the step S203, a cap layer is formed on the stress layer over the first-conductive-type transistor. This cap layer can be, for example, a photoresist layer and the material of the cap layer can be, for example, silicon oxide. The method for forming the cap layer can, for example, spin coating a photoresist layer or forming a silicon oxide layer by using chemical vapor deposition.

Next, in the step 204, a modification process is performed. The modification process includes thermal treatment, ion implantation, plasma treatment and oxidation treatment. In this embodiment, the thermal treatment comprises UV curing, spike annealing, E-beam annealing, laser annealing and UV rapid thermal process. The ion implantation comprises high energy ion implantation process and low energy ion implantation process. The plasma treatment and the oxidation treatment comprise high density plasma oxidation (HDPO) which utilizes, for example, oxygen, steam and ozone as the bearing gas.

In one embodiment, the first-conductive type transistor is a P-type transistor and the second-conductive-type transistor is an N-type transistor. After the modification process such as UV curing is performed, the tensile stress of the stress layer over the N-type transistor is increased for about 0.5 GPa˜3.0 GPa and the thickness of the stress layer over the N-type transistor is decreased for about 5%˜30% of the original thickness. Therefore, the driving current of the N-type transistor is increased.

In another embodiment, the first-conductive-type can be, for example, an N-type transistor and the second-conductive-type can be, for example, a P-type transistor. After the modification process, the compressive stress of the stress layer over the P-type transistor is increased so that the driving current of the P-type transistor is increased.

Then, in the step 205, after the modification process, the cap layer is removed.

Similarly, the stress layer of the present embodiment can be served as a CESL, a dual CESL and a poly-cap layer in the semiconductor device.

In this embodiment, since the cap layer covers the stress layer over the first-conductive-type transistor, the modification process does not affect the stress layer over the first-conductive-type transistor. Therefore, the stress, such as the tensile stress over the N-type transistor or the compressive stress over the P-type transistor, of the stress layer over the second-conductive-type transistor can be increased so as to increase the driving current of the second-conductive-type transistor. Meanwhile, this modification process dose not affect the stress of the stress layer over the first-conductive-type transistor so that the degradation of the driving current of the first-conductive-type transistor can be avoided.

### Third Embodiment

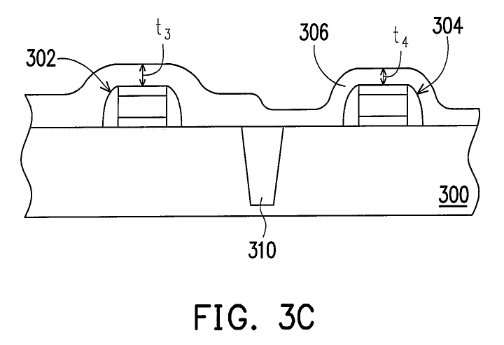

FIGS. 3A through 3C are cross-sectional views showing a method for fabricating a semiconductor device according to one embodiment of the present invention.

As shown in FIG. 3A, a substrate 300 is provided. The substrate 300 can be, for example, a bulk silicon substrate or a SOI substrate. The substrate 300 has a first-conductive-type transistor 302, a second-conductive-type transistor 304 and an isolation structure 310 formed thereon. In this embodiment, the first-conductive-type transistor 302 is a P-type transistor and the second-conductive-type transistor 304 is an N-type transistor. The isolation structure can be, for example, an STI structure or a field oxide layer formed by LOCOS.

As shown in FIG. 3A, a stress layer 306 is formed over the substrate 300 to conformally cover the first-conductive-type transistor 302 and the scone-conductive-type transistor 304. The material of the stress layer 306 can be, for example, selected from a group consisting of silicon nitride, polysilicon and silicon oxynitride. The method for forming the stress layer 306 can be, for example, a chemical vapor deposition.

The tensile stress of the stress layer 306 is about 0.5 GPa˜1.5 GPa. Preferably, the tensile stress of the stress layer 306 is about 1.0 GPa˜1.5 GPa. The thickness of the stress layer 306 is denoted as t3. Then, a cap layer 308 is formed on the stress layer 306 over the first-conductive-type transistor 302. This cap layer 308 can be, for example, a photoresist layer and the material of the cap layer 308 can be, for example, silicon oxide. The method for forming the cap layer 308 can be, for example, spin coating a photoresist layer or forming a silicon oxide layer by using the chemical vapor deposition.

As shown in FIG. 3B, a modification process M is performed on a portion of the stress layer 306 exposed by the cap layer 308. This modification process M includes thermal treatment, ion implantation, plasma treatment and oxidation treatment.

In this embodiment, the thermal treatment comprises a UV curing process. The wavelength of the UV light used in the UV curing process is about 100 nm˜400 nm and the UV curing process is performed at an environmental pressure of about 3 mTorr˜500 mTorr.

In another embodiment, the thermal treatment can be, for example, spike annealing, E-beam annealing, laser annealing or UV rapid thermal process.

The ion implantation in the modification process M comprises high energy ion implantation process and low energy ion implantation process. Moreover, the plasma treatment and the oxidation treatment comprise high density plasma oxidation which utilizes, for example, oxygen, steam and ozone as the bearing gas.

Then, as shown in FIG. 3C, after the modification process M, the cap layer 308 is removed. In this embodiment, the thickness of a portion of the stress layer 306 over the first-conductive-type transistor remains unchanged and is still denoted as t3. After the UV curing is performed, the thickness of a portion of the stress layer 306 over the second-conductive-type transistor 304 is decreased and is denoted as t4. Therefore, t3 is larger than t4 and t4 is about 5%˜30% thinner than t3. In addition, the tensile stress of the stress layer 306 over the second-conductive-type transistor 304 is 0.5 GPa˜3.0 GPa larger than it was before the UV curing is performed.

Similarly, the stress layer 306 of the present embodiment can be served as a CESL, a dual CESL or a poly-cap layer in the semiconductor device according to the designing requirement.

According to the aforementioned embodiment, the manufacturing process of the present invention is to form a stress layer with a continuous interface incorporating with a cap layer formation process and one modification process to reduce the volume of the stress layer over the N-type transistor. Thus, the volume of the stress layer over the N-type transistor is 5%˜30% smaller than that of the stress layer over the P-type transistor. Therefore, the stress is increased for about 0.5 GPa˜3.0 GPa. Hence, the driving current of the N-type transistor is increased. Meanwhile, because the cap layer covers a portion of the stress layer over the P-type transistor, the stress layer over the P-type transistor is not affected by the modification process. Therefore, the tensile stress of the stress layer over the P-type transistor is not increased and the performance of the P-type transistor is not affected. Comparing with the conventional manufacturing process, the manufacturing process of the present invention is more simplified and can regionally increase the tensile stress of the stress layer to decrease the effect on the performance of the P-type transistor. Therefore, the performance of the device can be effectively increased.

Altogether, in the embodiment for illustrating the manufacturing process of the present invention, by forming the stress layer with a continuous interface and performing one mask process and one modification process, the regional stress increment effect can be obtained. Comparing with the conventional process, the manufacturing process of the present invention is more simplified and the stress of the stress layer can be regionally increased. Therefore, the conventional phenomenon that the driving current of the N-type transistor is increased but the driving current of the P-type transistor is decreased can be avoided. In addition, according to the design demand of the semiconductor device, the present invention can be applied to increase the tensile stress of the N-type transistor or the compressive stress of the P-type transistor.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

1. A semiconductor device, comprising:
a substrate;
a first-conductive-type transistor and a second-conductive-type transistor disposed on the substrate; and
a stress layer disposed over the substrate to cover the first-conductive-type transistor and the second-conductive-type transistor, wherein the thickness of the stress layer over the first-conductive-type transistor is larger than that over the second-conductive-type transistor and the stress layer has a continuous interface.

2. The semiconductor device of claim 1, wherein the stress layer over the first-conductive-type transistor has a first thickness and the stress layer over the second-conductive-type transistor has a second thickness and the second thickness is 70%-90% of the first thickness.

3. The semiconductor device of claim 1, wherein the first-conductive-type transistor is a P-type transistor and the second-conductive-type transistor is an N-type transistor.

4. The semiconductor device of claim 3, wherein a tensile stress of the stress layer over the N-type transistor is larger than that of the stress layer over the P-type transistor.

5. The semiconductor device of claim 3, wherein the tensile stress of the stress layer over the N-type transistor is 0.5GPa˜3.0GPa larger than that of the stress layer over the P-type transistor.

6. The semiconductor device of claim 1, wherein a tensile stress of the stress layer over the first-conductive-type transistor is about 0.5GPa˜1.5GPa.

7. The semiconductor device of claim 1, wherein the material of the stress layer is selected from a group consisting of silicon nitride, polysilicon and silicon oxynitride.

8. The semiconductor device of claim 1, wherein the stress layer is served as an etching stop layer or a conductive cap layer.

9-28. (canceled)
